(19) United States
(12) Patent Application Publication
(10) Pub. No.: US 2025/0169178 A1
(43) Pub. Date: May 22, 2025

(54) 3D FET DEVICES AND METHODS FOR MANUFACTURING THE SAME

(71) Applicant: Tokyo Electron Limited, Tokyo (JP)

(72) Inventors: Mark I. GARDNER, Albany, NY (US); Henry Jim FULFORD, Albany, NY (US)

(73) Assignee: Tokyo Electron Limited, Tokyo (JP)

(21) Appl. No.: 18/597,779

(22) Filed: Mar. 6, 2024

Related U.S. Application Data
(60) Provisional application No. 63/599,844, filed on Nov. 16, 2023.

(51) Int. Cl. H01L 27/12; H01L 21/84

(52) U.S. Cl. CPC H10D 86/201; H10D 86/01

(57) ABSTRACT

Semiconductor devices and corresponding methods of manufacture are disclosed. The semiconductor device may include a semiconductor substrate including a first area and a second area; a first semiconductor structure disposed in the first area, vertically extending, and separated from the semiconductor substrate with a first dielectric structure interposed therebetween; a first transistor disposed around the first semiconductor structure, with the first semiconductor structure serving as a channel of the first transistor; a second semiconductor structure disposed in the second area, vertically extending, and in contact with the semiconductor substrate; and a second transistor disposed above the second semiconductor structure, with a third semiconductor structure laterally extending and serving as a channel of the second transistor.

### CROSS-REFERENCE TO RELATED APPLICATIONS

This application claims priority to U.S. Provisional Application No. 63/599,844, filed Nov. 16, 2023, which is incorporated by reference in its entirety.

### FIELD OF THE DISCLOSURE

The present disclosure relates generally to non-planar, or three-dimensional (3D), transistors structures and methods for manufacture the same.

### BACKGROUND

In the manufacture of semiconductor devices (especially on the microscopic scale), various fabrication processes are executed, for example, film-forming depositions, etch mask creation, patterning, material etching and removal, and doping treatments, among others. These processes can be performed repeatedly to form desired semiconductor device elements on a substrate. Historically, with microfabrication, transistors have been created in one plane, with wiring or metallization formed above the active device plane and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

Three-dimensional integration (e.g., the vertical stacking of multiple devices) aims to overcome scaling limitations experienced in planar devices by increasing transistor density in volume rather than area. Three-dimensional integration as applied to random logic designs is substantially more difficult than alternative approaches. Three-dimensional integration for logic chips (e.g., CPU (central processing unit), GPU (graphics processing unit), FPGA (field programmable gate array, SoC (System on a Chip), etc.) are being pursued.

The techniques described herein include methods and devices for Λ-3D fabrication of semiconductor devices. Specifically, techniques may include an integration method that allows for the integration of both horizontal and vertical nanosheets. The techniques result in a significant reduction in power consumption at the same operating frequency. Techniques herein can be used for various device integration flows with different channel doping and source/drain options.

Of course, the order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

At least one aspect of the present disclosure is directed to a semiconductor device. The semiconductor device may include a semiconductor substrate including a first area and a second area; a first semiconductor structure disposed in the first area, vertically extending, and separated from the semiconductor substrate with a first dielectric structure interposed therebetween; a first transistor disposed around the first semiconductor structure, with the first semiconductor structure serving as a channel of the first transistor; a second semiconductor structure disposed in the second area, vertically extending, and in contact with the semiconductor substrate; and a second transistor disposed above the second semiconductor structure, with a third semiconductor structure laterally extending and serving as a channel of the second transistor.

In some embodiments, the semiconductor device may comprise a second dielectric structure interposed between the second transistor and the second semiconductor structure. The second transistor can be disposed laterally next to the first transistor and vertically above the first transistor.

In some embodiments, the first transistor may further comprise: a first source/drain structure surrounding a first portion of the first semiconductor structure; a first gate structure surrounding a second portion of the first semiconductor structure; a second source/drain structure surrounding a third portion of the first semiconductor structure. The first source/drain structure can be disposed below the first gate structure and the first gate structure is disposed below the second source/drain structure. The first source/drain structure may laterally extend from the first semiconductor structure farther away than the first gate structure laterally extends from the first semiconductor structure, and the first gate structure laterally extends from the first semiconductor structure farther away than the second source/drain structure laterally extends from the first semiconductor structure.

In some embodiments, the second transistor may further comprise: a third source/drain structure vertically extending and in contact with a first end of the third semiconductor structure; a second gate structure surrounding the third semiconductor structure; a fourth source/drain structure vertically extending and in contact with a second end of the third semiconductor structure. Each of the first semiconductor structure and the second semiconductor structure can be an epitaxially grown structure from the semiconductor substrate. In some embodiments, the first and second semiconductor structures may have a first conductivity type, and the third semiconductor structure may have a second, opposite conductivity type.

In another aspect of the present disclosure, a semiconductor device may comprise: a first transistor and a second transistor. The first transistor may comprise: a first semiconductor structure vertically extending away and separated from the semiconductor substrate; a first source/drain structure surrounding the first semiconductor structure; a first gate structure surrounding the first semiconductor structure and disposed above the first source/drain structure; and a second source/drain structure surrounding the first semiconductor structure and disposed above the first gate structure. The second transistor can be disposed above a second semiconductor structure that vertically extends and is in contact with the semiconductor substrate. The second transistor may comprise: a third semiconductor structure laterally extending; a third source/drain structure in contact with a first end of the third semiconductor structure; a second gate structure surrounding the third semiconductor structure; and a fourth source/drain structure in contact with a second end of the third semiconductor structure.

In some embodiments, the semiconductor device may further comprise: a first dielectric structure vertically interposed between the first semiconductor structure and the semiconductor substrate; and a second dielectric structure vertically interposed between the second semiconductor structure and the second gate structure. The second dielectric structure can be disposed vertically above the first dielectric structure. The first dielectric structure may have its sidewall aligned with a sidewall of the first semiconductor structure. The second dielectric structure may have its sidewall aligned with a sidewall of the second semiconductor structure. Each of the first semiconductor structure and the second semiconductor structure can be an epitaxially grown structure from the semiconductor substrate.

In some embodiments, the first and second semiconductor structures may have a first conductivity type, and the third semiconductor structure may have a second, opposite conductivity type. The first source/drain structure may laterally extend from the first semiconductor structure farther away than the first gate structure laterally extends from the first semiconductor structure. The first gate structure may laterally extend from the first semiconductor structure farther away than the second source/drain structure laterally extends from the first semiconductor structure. In some embodiments, the first transistor may have a first conductivity type, and the second transistor may have a second, opposite conductivity type.

In yet another aspect, a method for fabricating semiconductor devices may comprise: epitaxially growing a first semiconductor structure and a second semiconductor structure from a semiconductor substrate, wherein the first and second semiconductor structures each extend in a vertical direction with a same height; replacing a bottom portion of the first semiconductor structure with a first dielectric structure; forming a first transistor around the first semiconductor structure; epitaxially growing first, second, third, and fourth semiconductor layers over the second semiconductor structure; replacing the first semiconductor layer with a second dielectric structure; and forming a second transistor above the second dielectric structure.

In some embodiments, the step of forming a first transistor may further comprise: forming a first source/drain structure surrounding a first portion of the first semiconductor structure, wherein the first source/drain structure is lifted from the semiconductor substrate by at least the first dielectric structure; forming a first gate structure surrounding a second portion of the first semiconductor structure that is located above the first portion; and forming a second source/drain structure surrounding a third portion of the first semiconductor structure that is located above the second portion. The step of forming a second transistor may further comprise: replacing the second and fourth semiconductor layers with a second gate structure; indenting the second gate structure; and forming a third source/drain structure and a fourth source/drain structure in contact with a first end and a second end of a third semiconductor layer, respectively.

These and other aspects and implementations are discussed in detail below. The foregoing information and the following detailed description include illustrative examples of various aspects and implementations and provide an overview or framework for understanding the nature and character of the claimed aspects and implementations. The drawings provide illustrations and a further understanding of the various aspects and implementations and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 is a flow chart of an example method for making a semiconductor device, in accordance with some embodiments.

FIGS. 2-19 each illustrate a cross-sectional view of a semiconductor device, during one of various fabrication stages, made by the method of FIG. 1, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Techniques herein include methods and devices for A (L)-3D fabrication of semiconductor devices. Specifically, techniques include a L-shaped field-effect transistor (FET) structure. The A (L)-3DFET device provides a horizontal and vertical nanosheet to be integrated for various device integration flows. The present disclosure demonstrates a single crystal flow utilizing Silicon and Ge for NMOS and PMOS, respectively, and includes the use of a continuous doping level between the source, channel, and drain as one example of its capabilities. This architecture results in a significant 30% reduction in power consumption at the same operation frequency. The present disclosure also encompasses various device integration flows with different channel doping and source/drain options, can be incorporated in all types of transistors and semiconductor materials.

Additionally, the A (L)-3DFET technology achieves lower parasitic resistances and capacitances, contributing to its improved performance. The present disclosure also includes an inverter logic element and all other logic elements within its scope. Furthermore, the present disclosure encompasses all transistor types and semiconductor single crystals, making it a comprehensive advancement in semiconductor device technology.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

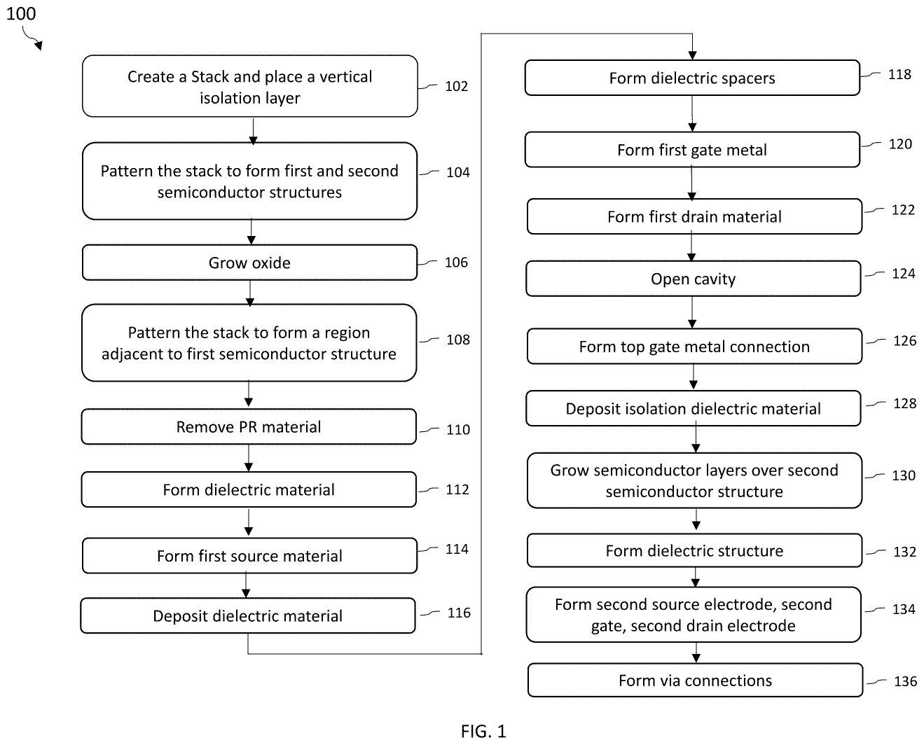

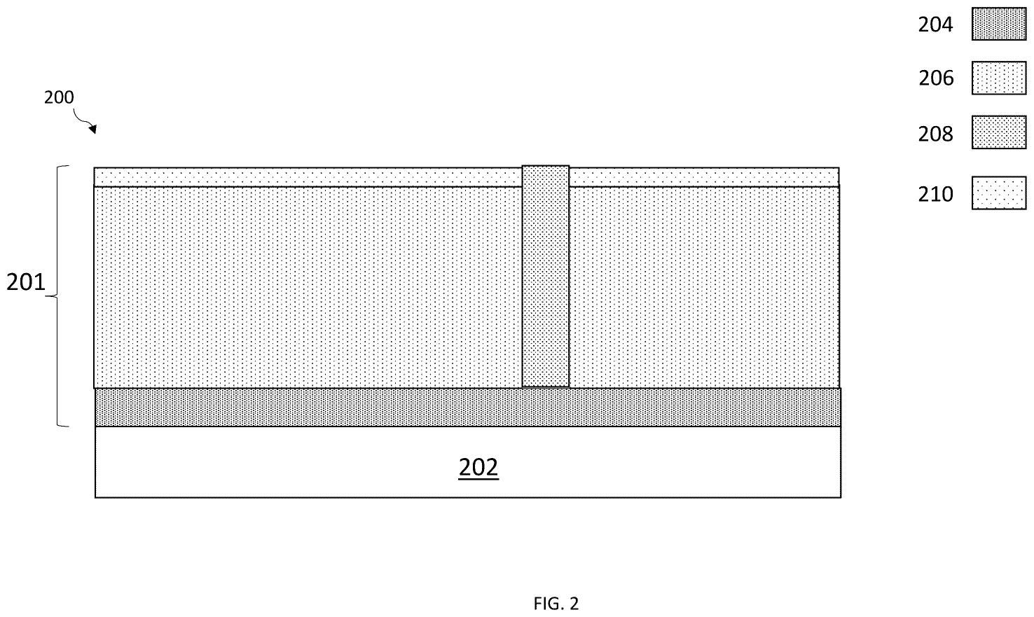

FIG. 1 illustrates a flowchart of an example method 100 for forming a semiconductor device including a Λ (L)—3D Field-Effect-Transistors (FET). For example, a semiconductor device include a semiconductor substrate including a first area and a second area; a first semiconductor structure disposed in the first area, vertically extending, and separated from the semiconductor substrate with a first dielectric structure interposed therebetween; a first transistor disposed around the first semiconductor structure, with the first semiconductor structure serving as a channel of the first transistor; a second semiconductor structure disposed in the second area, vertically extending, and in contact with the semiconductor substrate; and a second transistor disposed above the second semiconductor structure, with a third semiconductor structure laterally extending and serving as a channel of the second transistor. In various embodiments, operations of the method 100 may be associated with cross-sectional views of an example semiconductor device 200 including a number of such Λ (L)—3DFET at various fabrication stages as shown in FIGS. 2 to 19, which will be discussed in further detail below.

In brief overview, the method 100 starts with operation 102 of creating a stack and placing a vertical isolation layer. The method 100 proceeds to operation 104 of patterning the stack to form first and second semiconductor structures. The method 100 proceeds to operation 106 of growing oxide. The method 100 proceeds to operation 108 of patterning the stack to form a region adjacent to the first semiconductor structure. The method 100 proceeds to operation 110 of removing photoresist (PR) materials. The method 100 proceeds to operation 112 of forming dielectric structure. The method 100 proceeds to operation 114 of forming first source material. The method 100 proceeds to operation 116 of depositing dielectric material. The method 100 proceeds to operation 118 of forming dielectric spacers. The method 100 proceeds to operation 120 of forming first gate metal. The method 100 proceeds to operation 122 of forming first drain material. The method 100 proceeds to operation 124 of opening a cavity. The method 100 proceeds to operation 126 of forming top gate metal connection. The method 100 proceeds to operation 128 of depositing isolation dielectric material. The method 100 proceeds to operation 130 of growing semiconductor layers over the second semiconductor structure. The method 100 proceeds to operation 132 of forming a dielectric structure. The method 100 proceeds to operation 134 of forming a second source electrode, a second gate, and a second drain electrode. The method 100 proceeds to operation 136 of forming via connections.

Corresponding to operation 102 of FIG. 1, FIG. 2 is a cross-sectional view of the semiconductor device 200 in which a stack 201 can be formed on a substrate 202, at one of the various stages of fabrication, in accordance with various embodiments.

As shown, the stack 201, formed on the substrate 202, includes a number of dielectric materials of at least two different types: dielectric A generally denoted 204 and dielectric B generally denoted 206. Additionally, the stack 201 may be overlaid by a cap layer 210. Although the stack 201 has three layers including one dielectric A material 204, one dielectric B material 206 and one cap layer material 210 in the illustrated embodiment of FIG. 2, it should be understood that the stack 201 can include any number of dielectric A and B materials (204 and 206, respectively) and any number of cap layer materials 210 alternately stacked, while remaining within the scope of present disclosure.

In some embodiments, a vertical isolation layer 208 can be placed. The vertical isolation layer 208 can be made from a dielectric material, in accordance with various embodiments. The vertical isolation layer material may include at least one insulation material, which can electrically isolate neighboring active structures (e.g., metal electrodes which are formed above) from each other. The vertical isolation layer may be an oxide, such as a silicon oxide, a nitride, the like, or combinations thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. An anneal process may be performed once the insulation material is formed. In some embodiments, the vertical isolation layer may be formed by performing at least filling main openings with the dielectric material. Following the deposition of the dielectric material, an etching process may be performed to remove excessive dielectric material. Also, to complete the formation of the semiconductor device 200 after etching, the CMP can be performed to clean the top surface.

In various embodiments, the dielectric A and B materials (204 and 206, respectively) and the vertical isolation layer material 208 can have an etching selectively with respect to one or more other materials formed next to itself, allowing the dielectric material to be selectively removed while keeping the adjacent materials substantially intact (which will be discussed in further detail below).

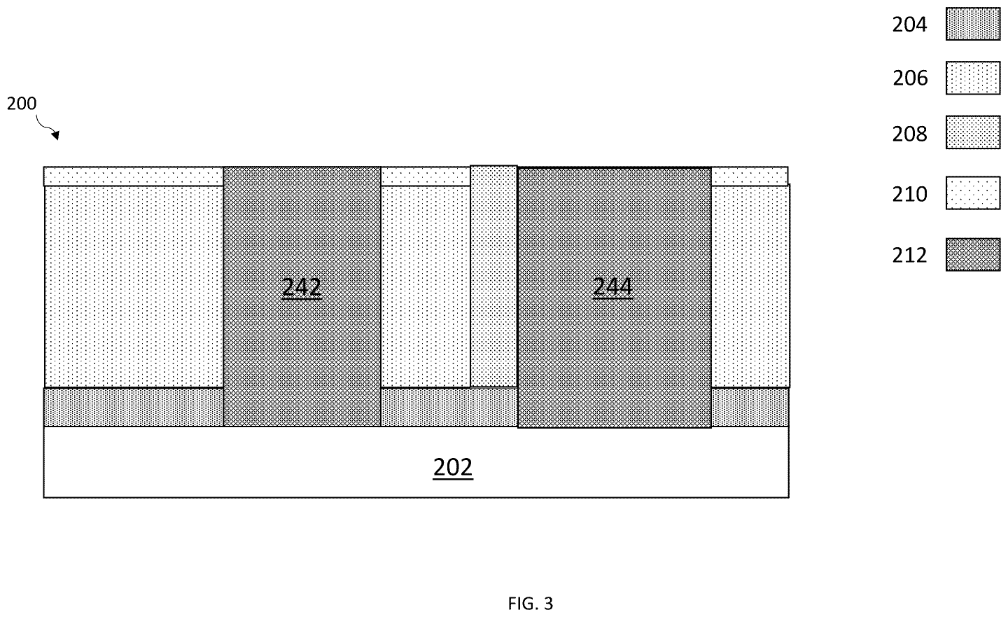

Corresponding to operation 104 of FIG. 1, FIG. 3 is a cross-sectional view of the semiconductor device 200 in which the stack 201 can be patterned, at one of the various stages of fabrication, in accordance with various embodiments.

The stack 201 may be patterned by performing at least one of the following processes: (1) forming a (e.g., photoresist) mask (not shown) on the stack 201; (2) etching the stack 201 to define a width and length of a first semiconductor structure 242 and a second semiconductor structure 244 using the mask; and (3) removing the mask. In some embodiments, the mask 210 may be formed on the cap layer 210. In some embodiments, the etching may be anisotropic (e.g., vertically applied over the workpiece), which allows the (patterned) stack 201 to have its sidewalls substantially aligned with the mask 210. In various embodiments, the removed portions of the stack 201, which exposes ends of each of the dielectric A and B materials (204 and 206 respectively) as well as the cap layer material 210, can define a first semiconductor structure 242 and a second semiconductor structure 244, as shown.

More specifically, one or more masks can be formed above the mask material using at least one suitable masking technique. Once the masks are formed, one or more etch techniques may be performed to remove the portion of the underlying materials aligned with the opening in the mask (e.g., portions of underlying materials not covered with the mask). Any type of suitable etching techniques may be used, including but not limited to dry etching, wet etching, or plasma etching techniques. The mask may be removed once the etching process to remove a portion of the materials is completed. Hereinafter, to remove one or more described materials, one or more masks and etching techniques can be used as discussed above. The etching process can remove materials in any geometry, such as vertically or diagonally. The dimension (e.g., width or diameter) of the masks can correspond to the dimension of the opening (e.g., removed portions of the materials) or the dimension of the underlying materials of the masks.

Following the formation of the hardmask layer (not shown), a patternable layer (e.g., a photoresist mask) with patterns is formed over the hardmask layer. Next, at least one dry etching or a wet etching process including, e.g., dilute hydrofluoric (DHF) acid, may be performed to etch the cap layer material 210, the dielectric B material 206, and the dielectric A material 204. Such etching is done until the substrate 202 material is exposed so as to form at least one opening. Further, the at least one opening can be formed with any of various cross-section profiles. For example, each of the at least one opening can have a square, triangular, circular, elliptical, or any other cross-section.

In the operation 104, a PR mask is applied and etched onto the substrate to create the desired shape for vertical 3D transistors (e.g., the first semiconductor structure 242 and the second semiconductor structure 244). Subsequently, a NNOS epitaxial layer is grown, ensuring uniform doping for the source, gate, and drain regions. Specifically, after forming the at least one opening, the first semiconductor structure 242 and the second semiconductor structure 244 can formed by epitaxially growing a semiconductor material 212 from the exposed the substrate 202. The growth process includes any of the following suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof. In some embodiments, the first 242 and second 244 semiconductor structures each extend in a vertical direction with a same height.

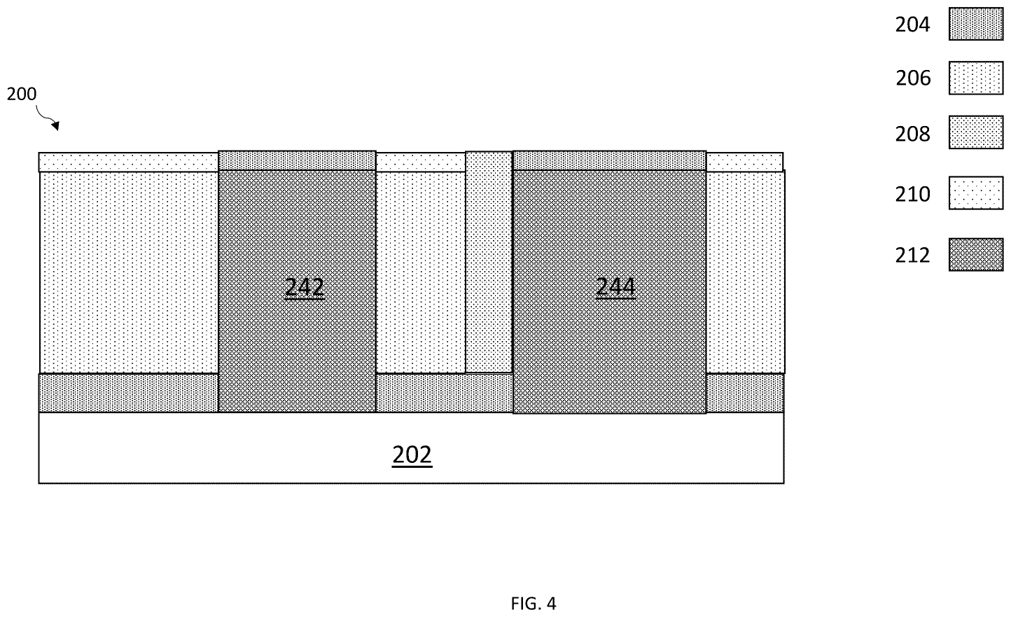

Corresponding to operation 106 of FIG. 1, FIG. 4 is a cross-sectional view of the semiconductor device 200 in which oxide materials 212 can be grown on top of the first 242 and second 244 semiconductor structures, at one of the various stages of fabrication, in accordance with various embodiments.

Following the growth of the NNOS epitaxial layer (e.g., the first 242 and second 244 semiconductor structures), an oxide layer 212 is grown on top of the first 242 and second 244 semiconductor structures. The oxide layer 212 serves as a protective coating for the upper surface of the semiconductor structures 242 and 244, safeguarding them from external factors and ensuring its integrity.

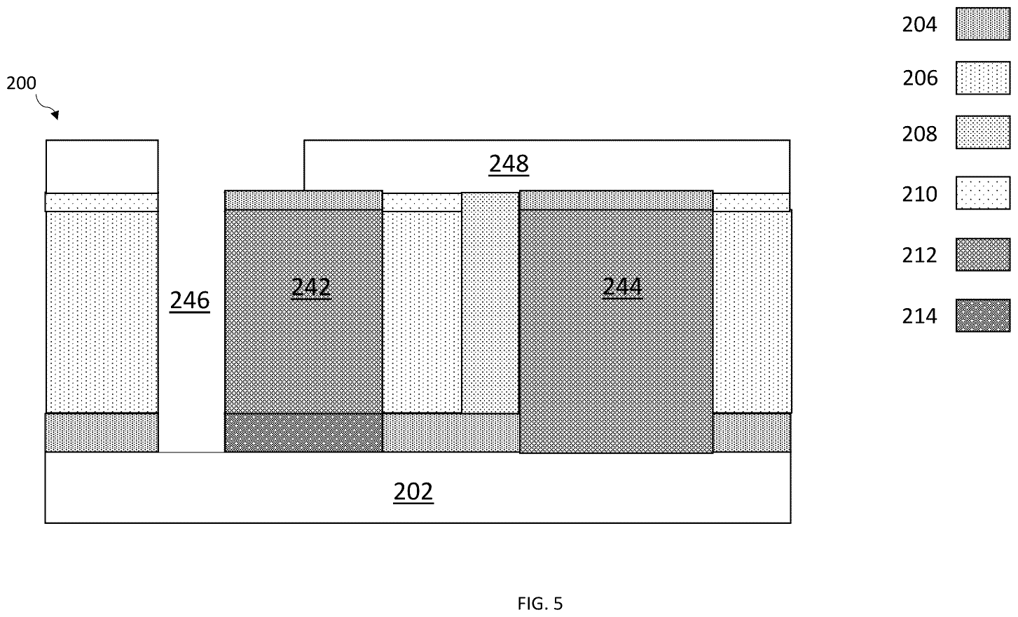

Corresponding to operation 108 of FIG. 1, FIG. 5 is a cross-sectional view of the semiconductor device 200 in which a region 246 can be formed adjacent to the first semiconductor structure 242, at one of the various stages of fabrication, in accordance with various embodiments.

The operation 108 involves the use of a photoresist (PR) mask 248 and etching to create an opening adjacent 246 to the previously grown epitaxial layer (e.g., the first semiconductor structure 242), as illustrated. It should be noted that only half of the cylinder is opened in this operation 108 before proceeding to etch it down to the substrate 202. In some embodiments, a bottom portion of the first semiconductor structure 242 can be replaced with a dielectric structure material 214.

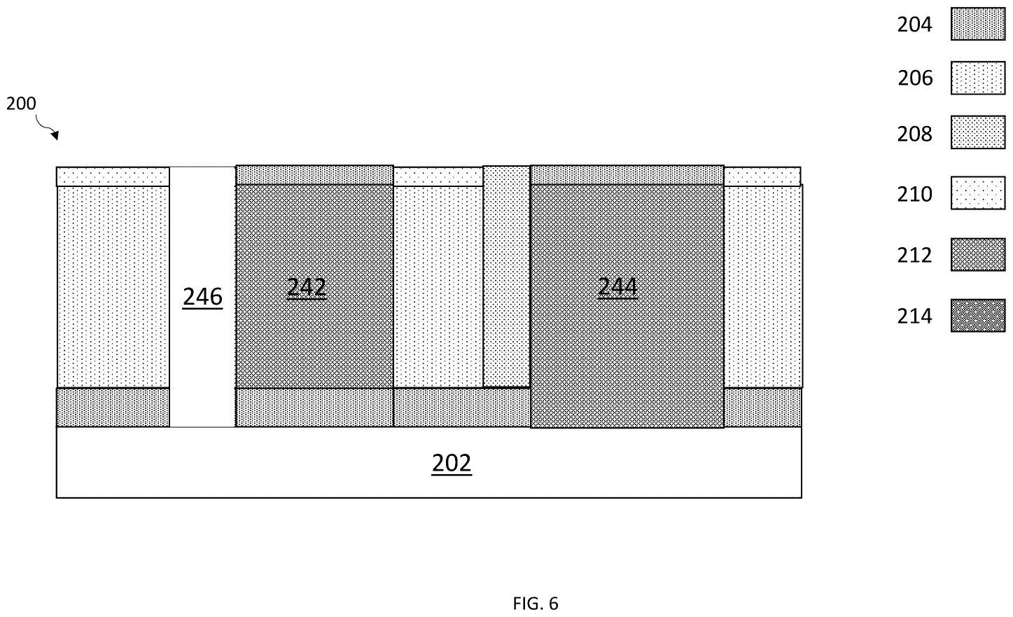

Corresponding to operation 110 of FIG. 1, FIG. 6 is a cross-sectional view of the semiconductor device 200 in which a photoresist (PR) material 248 can be removed, at one of the various stages of fabrication, in accordance with various embodiments.

In some embodiments, the photoresist (PR) material 248 is removed, followed by the removal of part of epitaxial layer and dielectric layers. This removal sequence is crucial as it effectively isolates the future vertical field-effect transistor (VFET) from the substrate 202. By eliminating these layers, a clear separation is established, setting the stage for the distinct operation of the VFET within the semiconductor device 200.

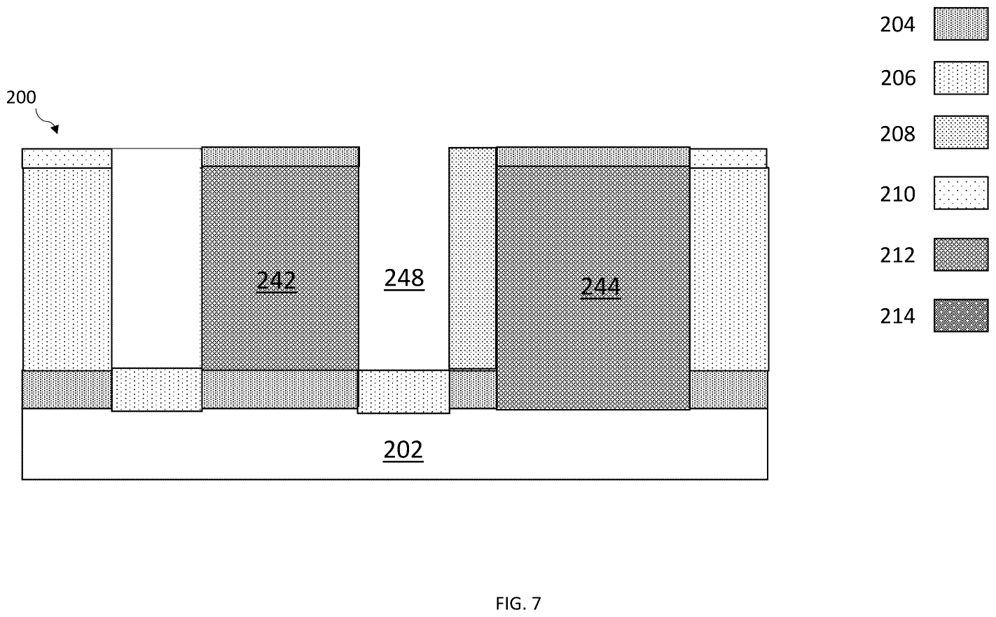

Corresponding to operation 112 of FIG. 1, FIG. 7 is a cross-sectional view of the semiconductor device 200 in which dielectric materials 206 can be formed, at one of the various stages of fabrication, in accordance with various embodiments.

In some embodiments, the process 100 continues with the filling of dielectric materials 206, followed by the application of a PR mask (not shown) and etching to open up a 360-degree region 248 around the epitaxial structure (e.g., the first semiconductor structure 242), as illustrated. The operation 112 ensures precise and controlled access to the epitaxial region 242 for subsequent processing, allowing for the proper integration of components within the semiconductor device 200.

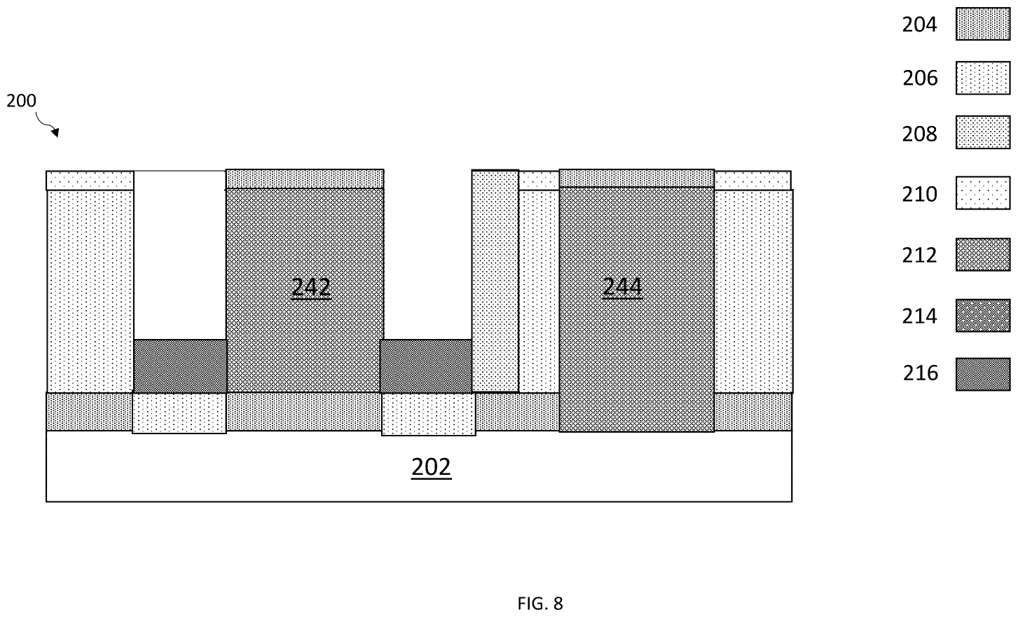

Corresponding to operation 114 of FIG. 1, FIG. 8 is a cross-sectional view of the semiconductor device 200 in which first source materials 216 can be formed, at one of the various stages of fabrication, in accordance with various embodiments.

In some embodiments, the source region 216 is prepared by depositing source materials onto the dielectric materials 206. Subsequently, a chemical mechanical polishing (CMP) can be employed to define the source metal 216, creating a well-defined and precise configuration for this source component within the semiconductor device 200. In certain embodiments, the growth process includes any of the following suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof.

In various embodiments, the source region 216 may be implanted with dopants to form doped source region 216 followed by an annealing process. For example, when the resulting transistor structure is an n-type transistor, the doped source region 216 can include silicon carbide (SiC), silicon phosphorous (SiP), phosphorous-doped silicon carbon (SiCP), or the like. When the resulting transistor structure is a p-type transistor, the source region 216 can include SiGe, and a p-type impurity such as boron or indium. In some embodiments, the source region 216 may be in situ doped during their growth.

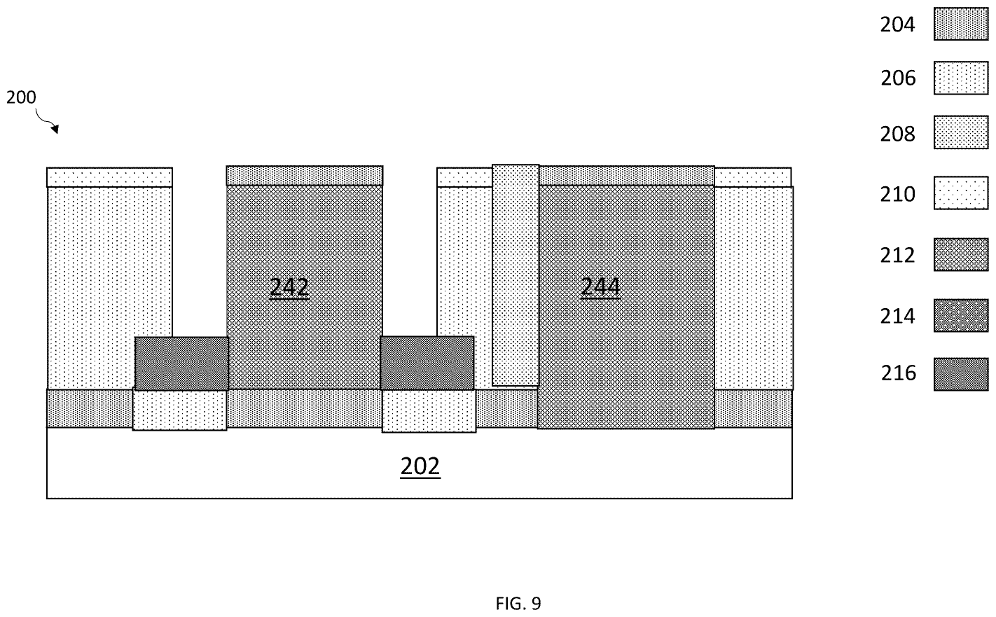

Corresponding to operation 116 of FIG. 1, FIG. 9 is a cross-sectional view of the semiconductor device 200 in which dielectric materials 206 can be formed, at one of the various stages of fabrication, in accordance with various embodiments.

In some embodiments, dielectric materials 206 is deposited, and a PR mask is applied. Subsequently, etching is performed as indicated in FIG. 9. This specific step facilitates the connection to the bottom source region 216 from a future top contact due to the wider source metal extension, ensuring effective electrical connections within the semiconductor device 200.

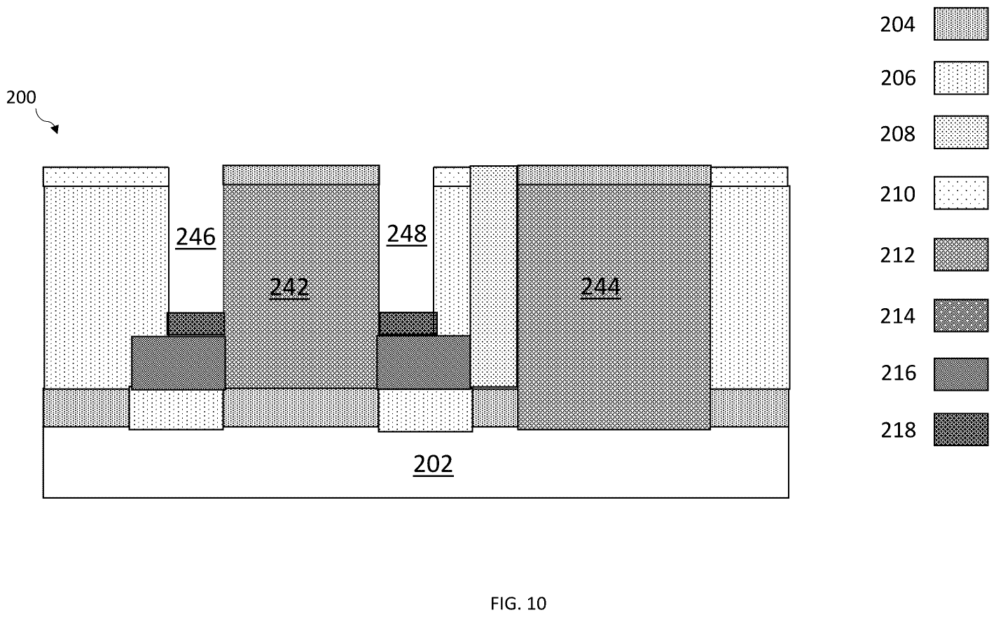

Corresponding to operation 118 of FIG. 1, FIG. 10 is a cross-sectional view of the semiconductor device 200 in which dielectric spacers 218 can be formed, at one of the various stages of fabrication, in accordance with various embodiments.

In some embodiments, an offset spacer 218 is deposited and subsequently etched. The operation 118 is for creating precise and controlled spacing within the semiconductor device 200, contributing to the overall functionality and performance of the components. According to some embodiments, a dielectric material may fill up the etched indents (openings) 246, 248 to form the dielectric spacers (or shells) 218. In some embodiments, the dielectric spacers 218 are configured to reduce coupling between a gate electrode and S/D metal material, thereby reducing parasitic capacitance induced therebetween. The dielectric material 218 may be an oxide, such as a silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof.

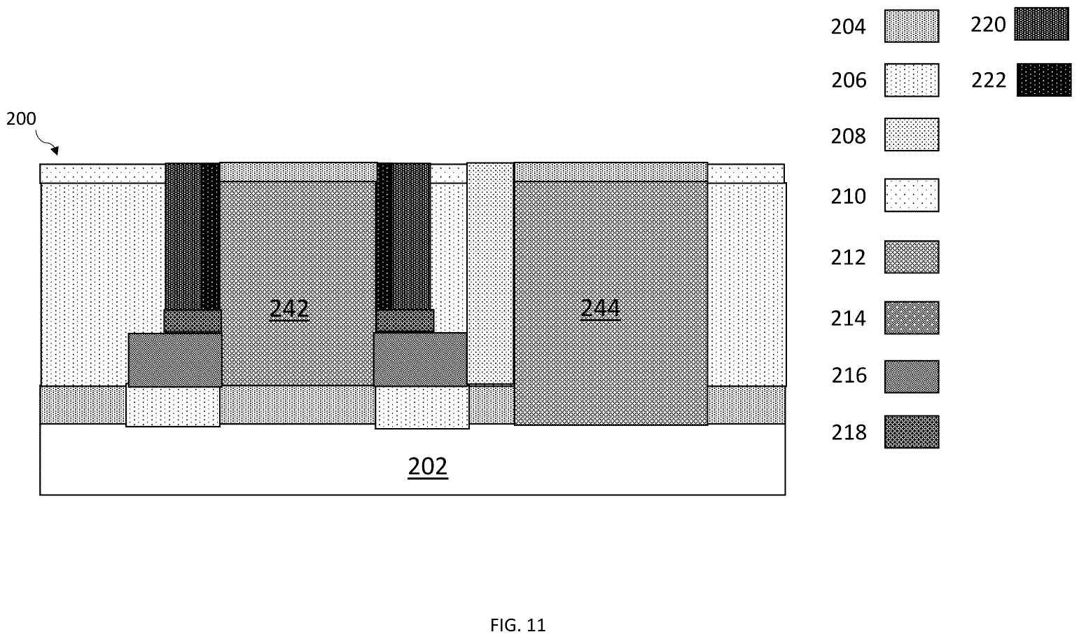

Corresponding to operation 120 of FIG. 1, FIG. 11 is a cross-sectional view of the semiconductor device 200 in which first gate metal 220 can be formed, at one of the various stages of fabrication, in accordance with various embodiments.

In some embodiments, the operation 120 involves the deposition of a gate dielectric material 222, followed by the deposition of a gate electrode material 220. Afterward, a chemical mechanical polishing (CMP) is employed to ensure the gate electrode is precisely defined, contributing to the proper functioning of the semiconductor device 200.

The gate dielectric material 222 can be any type of material that has a relatively large dielectric constant. As one example, a silicon oxide-based gate dielectric such as silicon dioxide (SiO2) may be selectively formed on a gate layer of silicon. Additionally or alternatively, other gate dielectric materials may be utilized such as silicon oxynitride (SiOxNy), silicon nitride (Si3N4), alumina (Al2O3), lanthanum oxide (La2O3), zirconium oxide (ZrO2), hafnium oxide (HfO2), hafnium zirconium oxide (HfZrO), tantalum oxide (Ta2O5), hafnium silicon oxide (HfSiO4), zirconium silicon oxide (ZrSiO4), titanium oxide (TiO2), strontium titanium oxide (SrTiO3), hafnium silicon oxynitride (HfSiOxNy), zirconium silicon oxynitride (ZrSiOxNy), hafnium oxynitride (HfOxNy), zirconium oxynitride (ZrOxNy), other suitable materials and combinations thereof.

The gate metal 220 may include a p-type work function layer, an n-type work function layer, multi-layers thereof, or combinations thereof, in some embodiments. Accordingly, the gate metal is sometimes referred to as a work function layer or work function metal. Example p-type work function metals that may be included in the gate structures for p-type devices include TiN, TaN, Ru, Mo, Al, WN, ZrSi₂, MoSi₂, TaSi₂, NiSi₂, WN, other suitable p-type work function materials, or combinations thereof. Example n-type work function metals that may be included in the gate structures for n-type devices include Ti, Ag, TaAl, TaAlC, TiAlN, TaC, TaCN, TaSiN, Mn, Zr, other suitable n-type work function materials, or combinations thereof.

The work function layer(s) may be deposited by CVD, physical vapor deposition (PVD), ALD, and/or other suitable process. The gate metal 220 may be formed by performing at least some of the following processes: (1) filling regions between the gate dielectric material 222 and the dielectric materials 206 with a gate metal material; and (2) performing a chemical mechanical polishing (CMP) process to remove excessive gate metal material until the cap layer 210 and the ends of the gate dielectric material 222 are aligned with the gate metal material 220. In some embodiments, an offset spacer 218 is deposited on the gate metal and subsequently etched.

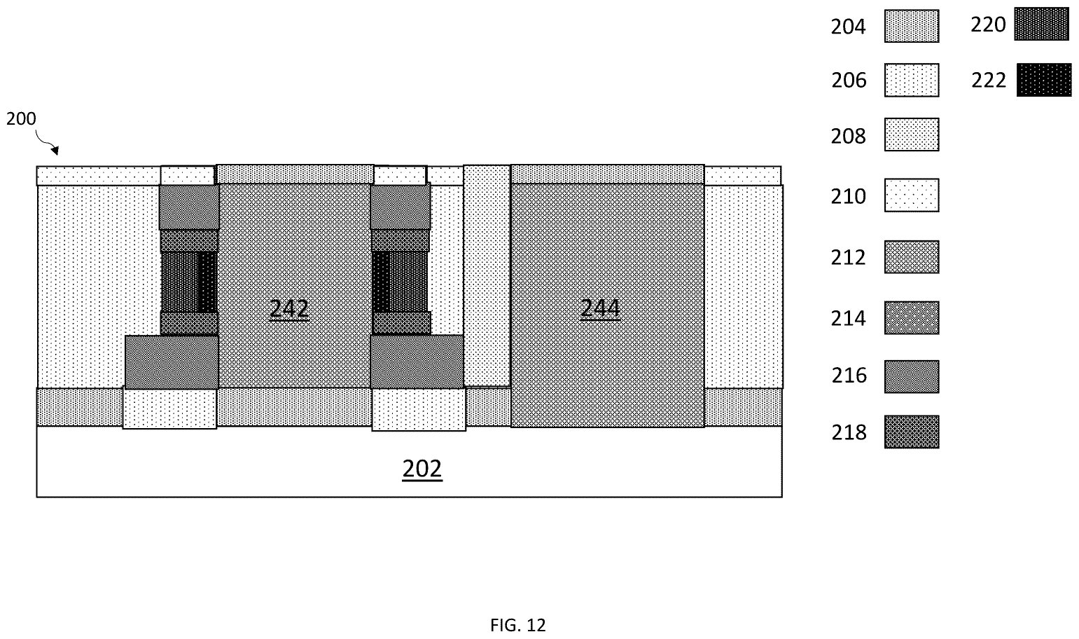

Corresponding to operation 122 of FIG. 1, FIG. 12 is a cross-sectional view of the semiconductor device 200 in which first drain materials 216 can be formed, at one of the various stages of fabrication, in accordance with various embodiments.

In some embodiments, dielectric materials can be deposited and subsequently etched. Following that, the gate metal 220 is etched, and then the gate dielectric 222 is etched as well. The operation 122 involves depositing and etching the drain region 216 as indicated in FIG. 12. A cap layer 210 is deposited to complete a first transistor around the first semiconductor structure 242.

In some embodiments, the drain region 216 is prepared by depositing drain materials onto the offset spacer 218. Subsequently, a chemical mechanical polishing (CMP) can be employed to define the drain metal 216, creating a well-defined and precise configuration for this source component within the semiconductor device 200. In certain embodiments, the growth process includes any of the following suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof.

In various embodiments, the drain region 216 may be implanted with dopants to form doped drain region 216 followed by an annealing process. For example, when the resulting transistor structure is an n-type transistor, the doped drain region 216 can include silicon carbide (SiC), silicon phosphorous (SiP), phosphorous-doped silicon carbon (SiCP), or the like. When the resulting transistor structure is a p-type transistor, the drain region 216 can include SiGe, and a p-type impurity such as boron or indium. In some embodiments, the drain region 216 may be in situ doped during their growth. In some embodiments, a first source/drain structure 216 surrounding a first portion of the first semiconductor structure 242 can be formed. The first source/drain structure 216 is lifted from the semiconductor substrate 202 by at least the first dielectric structure 206. A first gate structure surrounding a second portion of the first semiconductor structure 242 that is located above the first portion can be formed. A second source/drain structure 216 surrounding a third portion of the first semiconductor structure 242 that is located above the second portion can be formed.

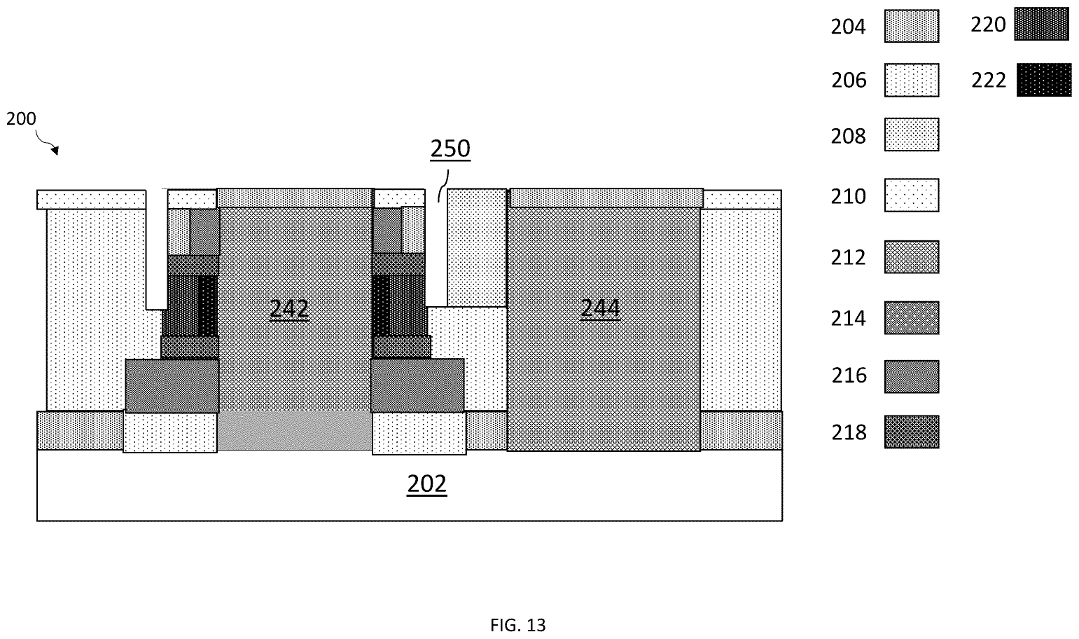

Corresponding to operation 124 of FIG. 1, FIG. 13 is a cross-sectional view of the semiconductor device 200 in which a cavity 250 can be opened, at one of the various stages of fabrication, in accordance with various embodiments.

In some embodiments, a cap layer 210 can be deposited and then subjected to chemical mechanical polishing (CMP) for precise surface leveling. Subsequently, a photoresist mask can be applied to open up a cavity 250, as shown in FIG. 13. Within this cavity 250, an indentation is etched into the drain region. Following this, dielectric materials 204 can be filled into the cavity 250, effectively separating the drain from the future gate electrode hookup. The operation 124 ensures proper isolation and functionality within the semiconductor device 200.

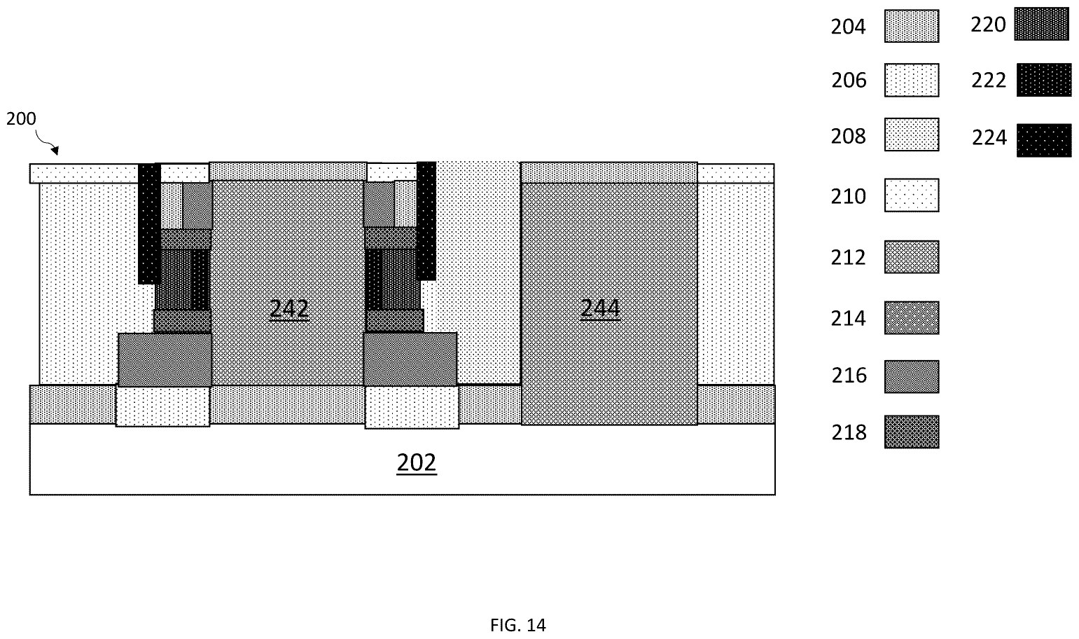

Corresponding to operation 126 of FIG. 1, FIG. 14 is a cross-sectional view of the semiconductor device 200 in which a top gate metal connection 224 can be formed, at one of the various stages of fabrication, in accordance with various embodiments.

In some embodiments, the top gate metal connection 224 can be established. Following this, a chemical mechanical polishing (CMP) can be performed to refine and ensure the precise configuration and connectivity of the top gate metal 224 within the semiconductor device 200. Upon the deposition, the S/D regions and/or gate electrodes can be (e.g., electrically) routed vertically.

In some embodiments, the gate metal connection 224 may include a conductive layer comprising any suitable conductive material, such as Cu, Al, W, Ru, other suitable materials, or combinations thereof. In some embodiments, the gate metal connection 224 may include the conductive layer over a barrier layer, which may include Ti, Ta, TiN, TaN, other suitable materials, or combinations thereof. The gate metal connection 224 deposition can be performed to complete the construction of the 3D vertical transistor (e.g., a first transistor).

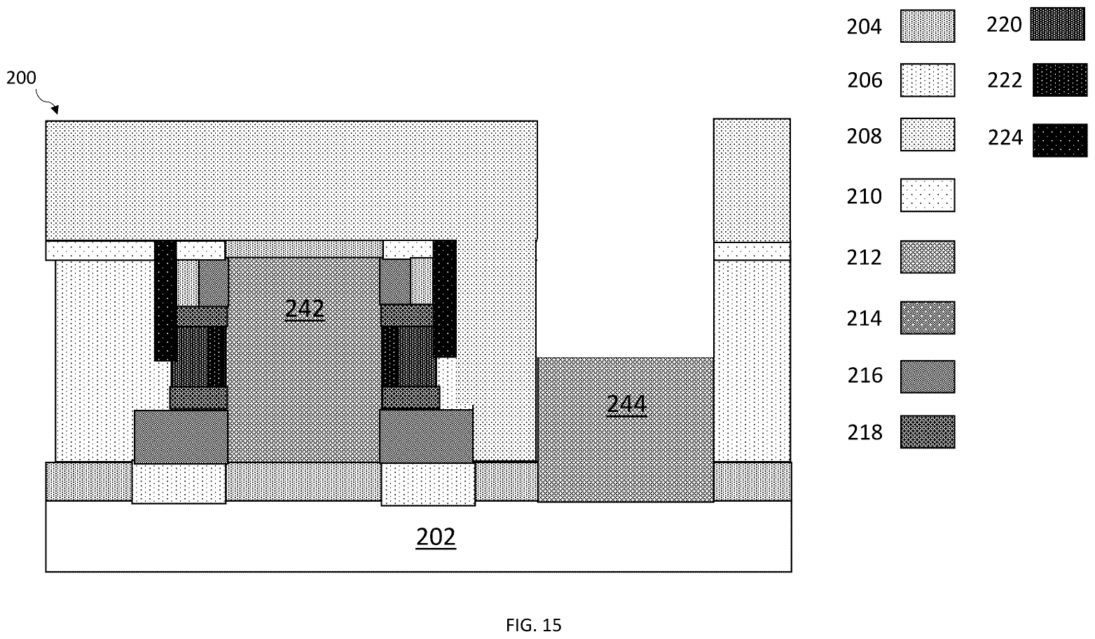

Corresponding to operation 128 of FIG. 1, FIG. 15 is a cross-sectional view of the semiconductor device 200 in which an isolation dielectric material 208 can be deposited, at one of the various stages of fabrication, in accordance with various embodiments.

In some embodiments, an isolation dielectric material 208 is deposited and subsequently etched according to the provided illustration in FIG. 15. Following this, the isolation dielectric material 208 on top of the right NMOS epitaxial layer (e.g., the second semiconductor structure 244) is removed. Additionally, the height of the right NMOS epitaxial layer can be reduced as depicted in the process 100.

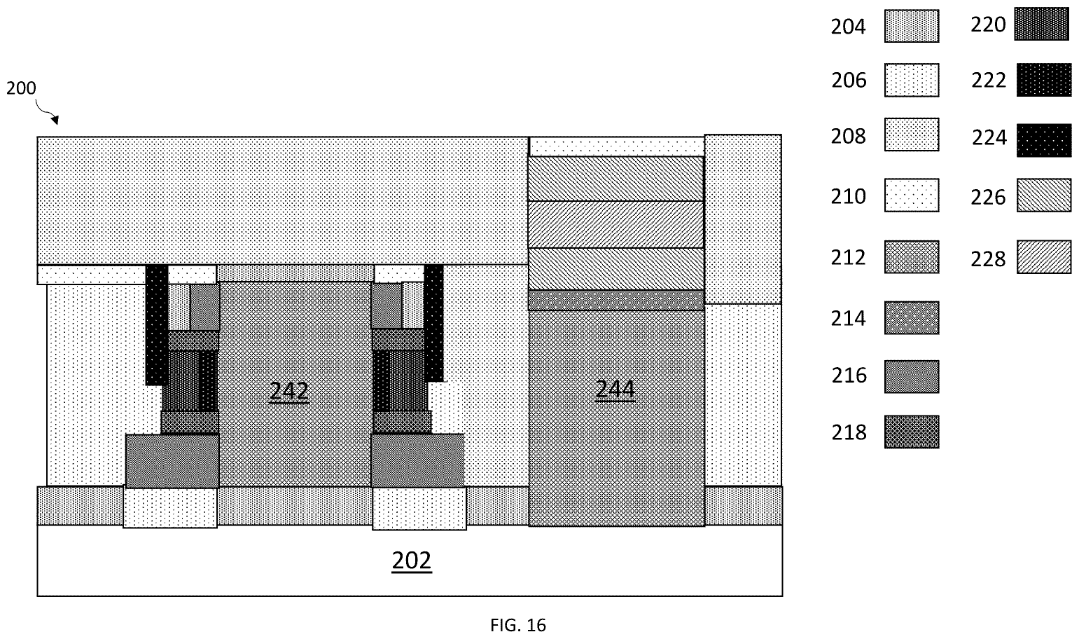

Corresponding to operation 130 of FIG. 1, FIG. 16 is a cross-sectional view of the semiconductor device 200 in which semiconductor layers can be deposited over the second semiconductor structure 244, at one of the various stages of fabrication, in accordance with various embodiments.

In some embodiments, the process 100 continues with the epitaxially growth of the dielectric structure material 214 (e.g., EPI 1), followed by the deposition of second epitaxial layer (e.g., EPI 2). Subsequently, the PMOS epitaxial layer (PMOS epi) can be grown, and another layer of EPI 2 can be deposited. A cap layer 210 is applied, as indicated in FIG. 16.

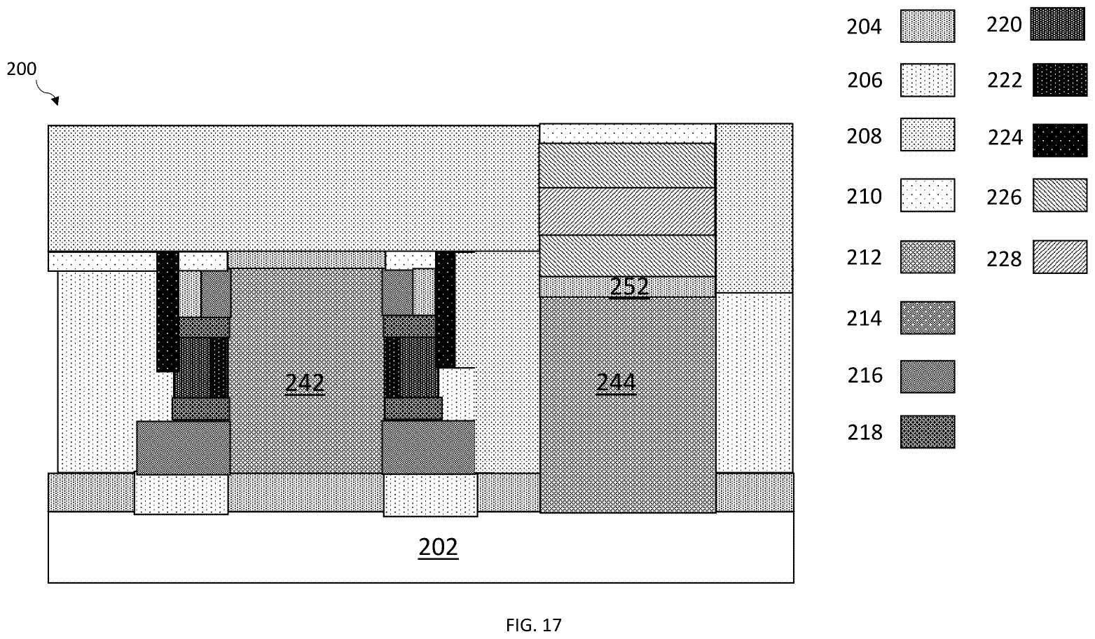

Corresponding to operation 132 of FIG. 1, FIG. 17 is a cross-sectional view of the semiconductor device 200 in which a dielectric structure can be formed, at one of the various stages of fabrication, in accordance with various embodiments.

In some embodiments, the sidewall of the PMOS epitaxial layer can be opened up, and EPI 1 is removed from that area. The first semiconductor layer 252 can be replaced with a second dielectric structure 204. Following this, the isolation dielectric material 208 can be filled into the space and subsequently etched. This process effectively isolates the NMOS epitaxial stack from the PMOS transistor. Subsequently, EPI 2 is removed, and the gate dielectric for the PMOS metal gate is established, completing the structural and functional elements within the semiconductor device 200.

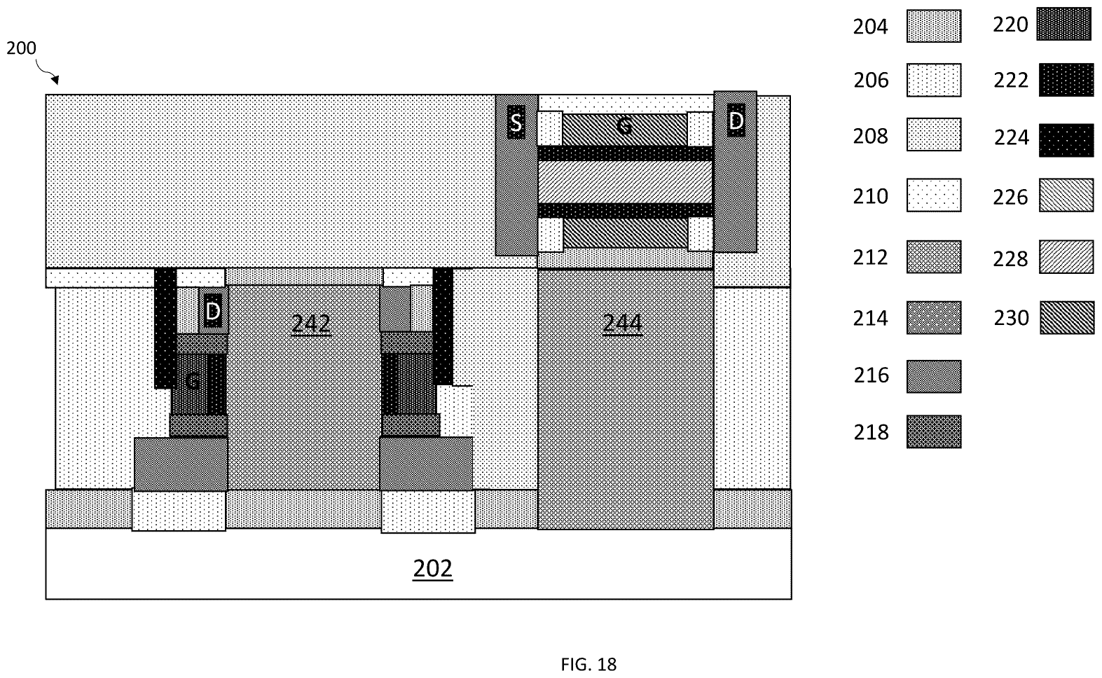

Corresponding to operation 134 of FIG. 1, FIG. 18 is a cross-sectional view of the semiconductor device 200 in which a second source electrode, a second gate, a second drain electrode of a second transistor can be formed, at one of the various stages of fabrication, in accordance with various embodiments.

In some embodiments, the second gate electrode may undergo an indentation etch. Afterward, the resulting indentation is filled with dielectric materials 206. Finally, a metal deposition is performed to complete the construction of the 3D horizontal transistor (e.g., a second transistor) on the right side of the semiconductor device 200.

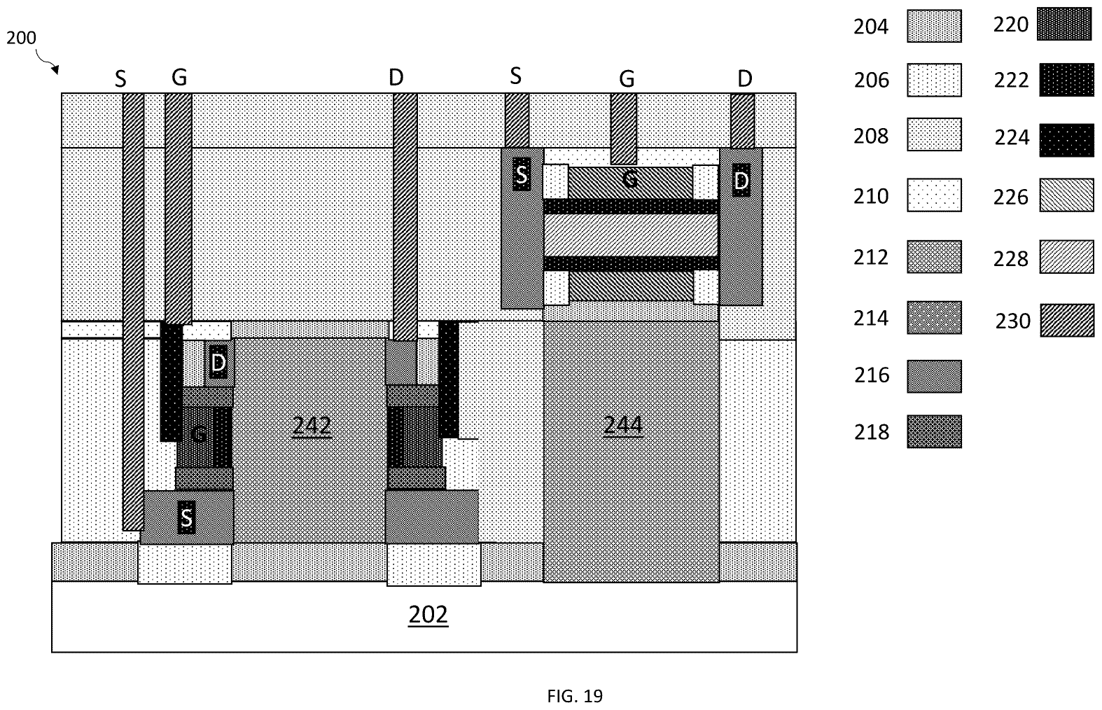

Corresponding to operation 136 of FIG. 1, FIG. 19 is a cross-sectional view of the semiconductor device 200 in which via connections can be formed, at one of the various stages of fabrication, in accordance with various embodiments.

The via connections each include a conductive layer comprising any suitable conductive material, such as Cu, Al, W, Ru, other suitable materials, or combinations thereof. In some embodiments, the via connections each include the conductive layer over a barrier layer, which may include Ti, Ta, TiN, TaN, other suitable materials, or combinations thereof.

The final cross-section of the A (L)-3DFET device, incorporating via connections, demonstrate an integrated semiconductor structure with multiple layers and precise geometries. The A (L)-3DFET device enables horizontal and vertical nanosheets to be integrated. The present disclosure demonstrates a single crystal flow utilizing Silicon and Ge for NMOS and PMOS, respectively, and includes the use of a continuous doping level between the source, channel, and drain as one example of its capabilities. This architecture results in a significant 30% reduction in power consumption at the same operation frequency, ensuring optimal performance and functionality.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a semiconductor substrate including a first area and a second area;
a first semiconductor structure disposed in the first area, vertically extending, and separated from the semiconductor substrate with a first dielectric structure interposed therebetween;
a first transistor disposed around the first semiconductor structure, with the first semiconductor structure serving as a channel of the first transistor;
a second semiconductor structure disposed in the second area, vertically extending, and in contact with the semiconductor substrate; and
a second transistor disposed above the second semiconductor structure, with a third semiconductor structure laterally extending and serving as a channel of the second transistor.

2. The semiconductor device of claim 1, further comprising a second dielectric structure interposed between the second transistor and the second semiconductor structure.

3. The semiconductor device of claim 1, wherein the second transistor is disposed laterally next to the first transistor and vertically above the first transistor.

4. The semiconductor device of claim 1, wherein the first transistor further comprises:
a first source/drain structure surrounding a first portion of the first semiconductor structure;
a first gate structure surrounding a second portion of the first semiconductor structure;
a second source/drain structure surrounding a third portion of the first semiconductor structure.

5. The semiconductor device of claim 4, wherein the first source/drain structure is disposed below the first gate structure and the first gate structure is disposed below the second source/drain structure.

6. The semiconductor device of claim 5, wherein the first source/drain structure laterally extends from the first semiconductor structure farther away than the first gate structure laterally extends from the first semiconductor structure, and the first gate structure laterally extends from the first semiconductor structure farther away than the second source/drain structure laterally extends from the first semiconductor structure.

7. The semiconductor device of claim 1, wherein the second transistor further comprises:
a third source/drain structure vertically extending and in contact with a first end of the third semiconductor structure;
a second gate structure surrounding the third semiconductor structure;
a fourth source/drain structure vertically extending and in contact with a second end of the third semiconductor structure.

8. The semiconductor device of claim 1, wherein each of the first semiconductor structure and the second semiconductor structure is an epitaxially grown structure from the semiconductor substrate.

9. The semiconductor device of claim 1, wherein the first and second semiconductor structures have a first conductivity type, and the third semiconductor structure has a second, opposite conductivity type.

10. A semiconductor device, comprising:
a first transistor comprising:
a first semiconductor structure vertically extending away and separated from the semiconductor substrate;
a first source/drain structure surrounding the first semiconductor structure;
a first gate structure surrounding the first semiconductor structure and disposed above the first source/drain structure; and
a second source/drain structure surrounding the first semiconductor structure and disposed above the first gate structure; and
a second transistor disposed above a second semiconductor structure that vertically extends and is in contact with the semiconductor substrate, and comprising:
a third semiconductor structure laterally extending;
a third source/drain structure in contact with a first end of the third semiconductor structure;
a second gate structure surrounding the third semiconductor structure; and
a fourth source/drain structure in contact with a second end of the third semiconductor structure.

11. The semiconductor device of claim 10, further comprising:
a first dielectric structure vertically interposed between the first semiconductor structure and the semiconductor substrate; and
a second dielectric structure vertically interposed between the second semiconductor structure and the second gate structure.

12. The semiconductor device of claim 11, wherein the second dielectric structure is disposed vertically above the first dielectric structure.

13. The semiconductor device of claim 11, wherein the first dielectric structure has its sidewall aligned with a sidewall of the first semiconductor structure, and the second dielectric structure has its sidewall aligned with a sidewall of the second semiconductor structure.

14. The semiconductor device of claim 10, each of the first semiconductor structure and the second semiconductor structure is an epitaxially grown structure from the semiconductor substrate.

15. The semiconductor device of claim 10, wherein the first and second semiconductor structures have a first conductivity type, and the third semiconductor structure has a second, opposite conductivity type.

16. The semiconductor device of claim 10, wherein the first source/drain structure laterally extends from the first semiconductor structure farther away than the first gate structure laterally extends from the first semiconductor structure, and the first gate structure laterally extends from the first semiconductor structure farther away than the second source/drain structure laterally extends from the first semiconductor structure.

17. The semiconductor device of claim 10, wherein the first transistor has a first conductivity type, and the second transistor has a second, opposite conductivity type.

18. A method for fabricating semiconductor devices, comprising:
epitaxially growing a first semiconductor structure and a second semiconductor structure from a semiconductor substrate, wherein the first and second semiconductor structures each extend in a vertical direction with a same height;
replacing a bottom portion of the first semiconductor structure with a first dielectric structure;
forming a first transistor around the first semiconductor structure;
epitaxially growing first, second, third, and fourth semiconductor layers over the second semiconductor structure;
replacing the first semiconductor layer with a second dielectric structure; and
forming a second transistor above the second dielectric structure.

19. The method of claim 18, wherein the step of forming a first transistor further comprises:
forming a first source/drain structure surrounding a first portion of the first semiconductor structure, wherein the first source/drain structure is lifted from the semiconductor substrate by at least the first dielectric structure;
forming a first gate structure surrounding a second portion of the first semiconductor structure that is located above the first portion; and
forming a second source/drain structure surrounding a third portion of the first semiconductor structure that is located above the second portion.

20. The method of claim 18, wherein the step of forming a second transistor further comprises:
replacing the second and fourth semiconductor layers with a second gate structure;
indenting the second gate structure; and
forming a third source/drain structure and a fourth source/drain structure in contact with a first end and a second end of a third semiconductor layer, respectively.
